(19) United States
(12) Patent Application Publication
(10) Pub. No.: US 2026/0269815 A1
(43) Pub. Date: Sep. 10, 2026

(54) DIGITAL ISOLATOR

(71) Applicants: Kabushiki Kaisha Toshiba, Kawasaki-shi (JP); Toshiba Electronic Devices & Storage Corporation, Kawasaki-shi (JP)

(72) Inventor: Kazuya KOBAYASHI, Yokohama Kanagawa (JP)

(21) Appl. No.: 19/354,179

(22) Filed: Oct. 9, 2025

(30) Foreign Application Priority Data
Mar. 7, 2025 (JP) 2025-036260

(51) Int. Cl. H03K 5/125; H03K 17/687; H03K 5/00; H03K 19/20

(52) U.S. Cl. CPC H03K 5/125; H03K 17/6871; H03K 2005/00078; H03K 19/20

(57) ABSTRACT

According to one embodiment, a digital isolator includes: an edge detection circuit outputs a first detection signal and a second detection signal; a refresh circuit outputs a first refresh signal and a second refresh signal; a driving buffer circuit outputs a first drive signal and a second drive signal; an isolation element outputs a first edge signal and a second edge signal corresponding to the first drive signal and the second drive signal respectively; a switch circuit switches a conduction state between the first output terminal and the second output terminal respectively and a reference potential; and a refresh detection circuit outputs a negative potential detection signal regarding the first edge signal or the second edge signal.

### CROSS-REFERENCE TO RELATED APPLICATION

This application is based upon and claims the benefit of priority from Japanese Patent Application No. 2025-036260, filed Mar. 7, 2025, the entire contents of which are incorporated herein by reference.

### FIELD

Embodiments described herein relate generally to a digital isolator.

### BACKGROUND

A digital isolator of an edge transmission system with one shot pulse is known.

### BRIEF DESCRIPTION OF DRAWINGS

FIG. 1 is a diagram illustrating an example of a configuration of a digital isolator according to an embodiment.

FIG. 2 is a circuit diagram illustrating an example of a configuration of a primary circuit of the digital isolator according to the embodiment.

FIG. 3 is a circuit diagram illustrating an example of a configuration of a secondary circuit of the digital isolator according to the embodiment.

FIG. 4 is a circuit diagram illustrating an example of a configuration of a refresh detection circuit of the digital isolator according to the embodiment.

FIG. 5 is a circuit diagram illustrating an example of detection of a negative potential pulse by the refresh detection circuit of the digital isolator according to the embodiment.

FIG. 6 is a timing chart illustrating an example of an operation of the digital isolator according to the embodiment.

FIG. 7 is a circuit diagram illustrating an example of a configuration of a refresh detection circuit of a digital isolator according to a first modification.

FIG. 8 is a circuit diagram illustrating an example of detection of a negative potential pulse by the refresh detection circuit of the digital isolator according to the first modification.

FIG. 9 is a circuit diagram illustrating an example of a configuration of a refresh detection circuit of a digital isolator according to a second modification.

FIG. 10 is a circuit diagram illustrating an example of detection of a negative potential pulse by the refresh detection circuit of the digital isolator according to the second modification.

FIG. 11 is a circuit diagram illustrating an example of a configuration of a secondary circuit of a digital isolator according to a third modification.

FIG. 12 is a timing chart illustrating an example of the operation of the digital isolator according to the third modification.

FIG. 13 is a circuit diagram illustrating an example of a configuration of a secondary circuit of a digital isolator according to a fourth modification.

FIG. 14 is a timing chart illustrating an example of the operation of the digital isolator according to the fourth modification.

### DETAILED DESCRIPTION

In general, according to one embodiment, a digital isolator of an edge transmission type, includes: an edge detection circuit that detects an edge of a first signal according to an input signal having a first level or a second level and outputs a first detection signal generated using an edge of a first polarity of the first signal and a second detection signal generated using an edge of a second polarity of the first signal different from the first polarity; a refresh circuit that generates a refresh pulse based on the input signal and outputs a first refresh signal generated corresponding to the first level using the refresh pulse and a second refresh signal generated corresponding to the second level using the refresh pulse; a driving buffer circuit that outputs a first drive signal generated using the first detection signal and the first refresh signal and a second drive signal generated using the second detection signal and the second refresh signal; an isolation element in which the first drive signal and the second drive signal are input to a primary side, a first edge signal corresponding to the first drive signal is output from a first output terminal on a secondary side, and a second edge signal corresponding to the second drive signal is output from a second output terminal on a secondary side; a latch circuit that latches data generated using the first edge signal and the second edge signal and outputs an output signal corresponding to the data; a first switch circuit including a first switch element that switches a conduction state between a reference potential and the first output terminal by using the output signal and a second switch element that switches a conduction state between the reference potential and the second output terminal; a first control circuit that turns on one switch element of the first switch element and the second switch element and turns off the other switch element by using the output signal; and a refresh detection circuit that outputs a negative potential detection signal according to whether the first edge signal or the second edge signal is lower than or equal to a first potential lower than the reference potential.

The embodiments will be described with reference to the drawings. Note that, in the following description, components having the same function and configuration are denoted by the same reference numerals.

### 1. Embodiments

A digital isolator according to an embodiment will be described.

### 1.1 Configuration

A configuration of a digital isolator according to an embodiment will be described.

### 1.1.1 Overall Configuration of Digital Isolator

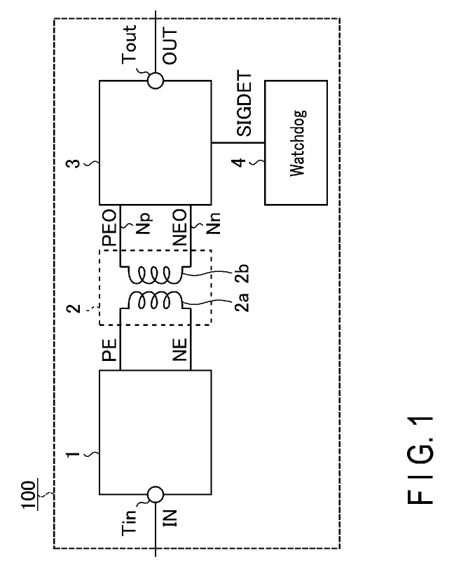

A configuration of a digital isolator according to an embodiment will be described with reference to FIG. 1. FIG. 1 is a diagram illustrating an example of a configuration of a digital isolator according to an embodiment.

A digital isolator 100 is, for example, an integrated circuit (IC) chip. The digital isolator 100 includes a primary circuit 1, an isolation element 2, a secondary circuit 3, and a watchdog 4. Note that the watchdog 4 may be configured outside the digital isolator 100.

The digital isolator 100 further includes terminals Tin and Tout. A signal IN is input to the terminal Tin from the outside of the digital isolator 100. The signal IN has, for example, an “H (High)” level or an “L (Low)” level. The signal IN is also referred to as an input signal. A signal OUT is output from the terminal Tout to a load outside the digital isolator 100 (not illustrated). The signal OUT is also referred to as an output signal. The terminals Tin and Tout are also referred to as an input terminal and an output terminal, respectively.

The primary circuit 1 generates signals PE and NE by using the signal IN input to the terminal Tin. Further, the primary circuit 1 outputs the signals PE and NE to the isolation element 2. The signals PE and NE are also referred to as drive signals. The configuration of the primary circuit 1 and the signals PE and NE will be described later in more detail.

The isolation element 2 includes, for example, coils 2a and 2b. The coils 2a and 2b configure a transformer. The coil 2a is also referred to as a primary coil. The coil 2b is also referred to as a secondary coil.

One end and another end of the coil 2a are coupled to the primary circuit 1. More specifically, the signals PE and NE are input from the primary circuit 1 to one end and another end of the coil 2a, respectively.

One end and another end of the coil 2b are coupled to the secondary circuit 3. Signals PEO and NEO are output from one end and another end of the coil 2b to the secondary circuit 3, respectively. The signals PEO and NEO are signals to which the signals PE and NE are transmitted by the transformers, respectively. The signals PEO and NEO are also referred to as edge signals. Hereinafter, one end of the coil 2b is also referred to as a node Np or a first output terminal. Another end of the coil 2b is also referred to as a node Nn or a second output terminal.

The signals PEO and NEO are input from the isolation element 2 to the secondary circuit 3. The secondary circuit 3 generates the signal OUT using the signals PEO and NEO. Further, the secondary circuit 3 outputs the signal OUT to a load outside the digital isolator 100.

Further, the secondary circuit 3 generates a signal SIGDET using the signals PEO and NEO. Then, the secondary circuit 3 outputs the signal SIGDET to the watchdog 4.

The configuration of the secondary circuit 3 and the signals PEO, NEO, and SIGDET will be described later in more detail.

The watchdog 4 is coupled to the secondary circuit 3. The watchdog 4 is configured to be able to detect a loss of a power supply of the primary circuit 1 based on the signal SIGDET generated by the secondary circuit 3. For example, the watchdog 4 stops the supply of power from the terminal Tout based on the detection result.

### 1.1.2 Configuration of Primary Circuit

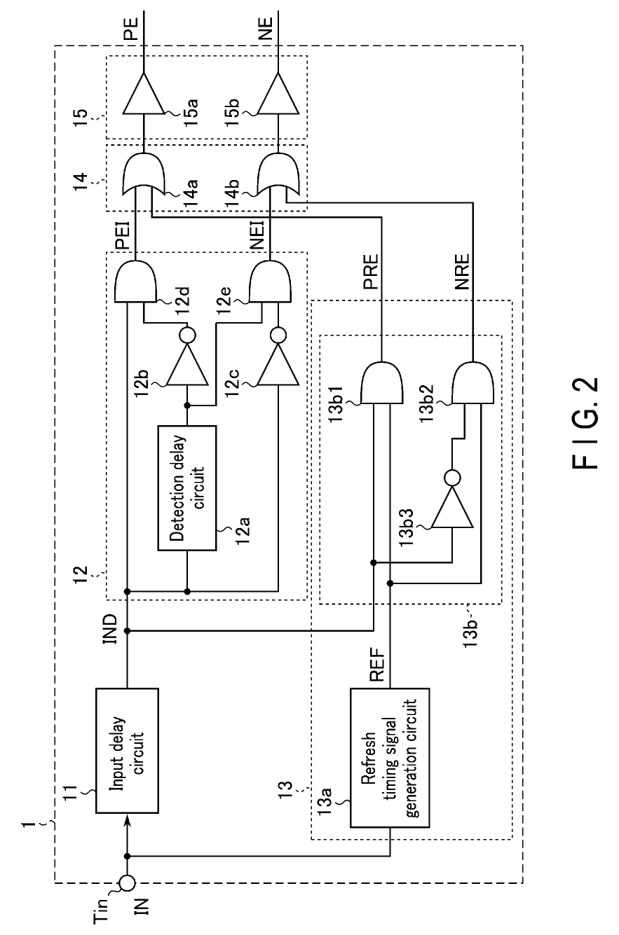

The configuration of the primary circuit 1 will be described with reference to FIG. 2. FIG. 2 is a circuit diagram illustrating an example of the configuration of the primary circuit of the digital isolator according to the embodiment.

The primary circuit 1 includes an input delay circuit 11, an edge detection circuit 12, a refresh circuit 13, an addition circuit 14, and a driving buffer circuit 15.

The input delay circuit 11 is coupled to the terminal Tin. As a result, the signal IN is input to the input delay circuit 11. The input delay circuit 11 generates a signal IND obtained by delaying the signal IN. Then, the input delay circuit 11 outputs the signal IND.

The edge detection circuit 12 includes a detection delay circuit 12a, inverters 12b and 12c, and AND circuits 12d and 12e.

The signal IND is input to the detection delay circuit 12a. The detection delay circuit 12a generates a signal obtained by delaying the signal IND. Then, the detection delay circuit 12a outputs the signal to each of the inverter 12b and the AND circuit 12e.

The signal delayed by the detection delay circuit 12a is input to the inverter 12b. The inverter 12b generates a signal obtained by inverting the signal. Then, the inverter 12b outputs the generated signal to the AND circuit 12d.

The signal IND is input to the inverter 12c. The inverter 12c generates a signal obtained by inverting the signal IND. Then, the inverter 12c outputs the generated signal to the AND circuit 12e.

The AND circuit 12d has a first terminal, a second terminal, and an output terminal. The signal IND is input to the first terminal. A signal output from the inverter 12b is input to the second terminal. The AND circuit 12d performs a logical product (AND) operation of the two signals input to the first terminal and the second terminal. The AND circuit is also called a logical product operation circuit. Then, the AND circuit 12d outputs a signal PEI generated by the operation from the output terminal. The signal PEI is also referred to as a detection signal.

The AND circuit 12e has a first terminal, a second terminal, and an output terminal. A signal delayed by the detection delay circuit 12a is input to the first terminal. A signal output from the inverter 12c is input to the second terminal. The AND circuit 12e performs an AND operation of the two signals input to the first terminal and the second terminal. Then, the AND circuit 12e outputs the signal NEI generated by the operation from the output terminal. The signal NEI is also referred to as a detection signal.

With the above configuration, the edge detection circuit 12 is configured to detect an edge of the signal IND. More specifically, the edge detection circuit 12 detects a rising edge of the signal IND and a falling edge of the signal IND. In the following example, the rising edge of the signal and the falling edge of the signal are also referred to as an edge of a first polarity and an edge of a second polarity, respectively. The edge detection circuit 12 outputs the signals PEI and NEI according to the polarity of the edge of the signal IND. For example, the edge detection circuit 12 outputs a pulse of the signal PEI according to the edge of the first polarity. Further, for example, the edge detection circuit 12 outputs a pulse of the signal NEI according to the edge of the second polarity. The signals PEI and NEI are also referred to as detection signals.

The refresh circuit 13 includes a refresh timing signal generation circuit 13a and a polarity setting circuit 13b.

The signal IN is input to the refresh timing signal generation circuit 13a. For example, the refresh timing signal generation circuit 13a outputs a pulse of a signal REF every time it is detected that the signal IN does not change between the “H” level and the “L” level for a preset period. The pulse is also called a refresh pulse.

The polarity setting circuit 13b includes AND circuits 13b1 and 13b2 and an inverter 13b3.

The AND circuit 13b1 includes a first terminal, a second terminal, and an output terminal. The signal IND is input to the first terminal. The signal REF is input to the second terminal. The AND circuit 13b1 executes an AND operation of the signals IND and REF. Then, the AND circuit 13b1 outputs a signal PRE generated by the operation from the output terminal.

The signal IND is input to the inverter 13b3. The inverter 13b3 generates a signal obtained by inverting the signal IND. Then, the inverter 13b3 outputs the generated signal to the AND circuit 13b2.

The AND circuit 13b2 includes a first terminal, a second terminal, and an output terminal. A signal output from the inverter 13b3 is input to the first terminal. The signal REF is input to the second terminal. The AND circuit 13b2 executes an AND operation of the signal input to the first terminal and the signal REF. Then, the AND circuit 13b2 outputs a signal NRE generated by the operation from the output terminal to the addition circuit 14.

With the above configuration, the refresh circuit 13 outputs the signals PRE and NRE for refreshing data using the signal REF based on the presence or absence of a change in the signal IN and the signal IND. The signals PRE and NRE are also called refresh signals.

The addition circuit 14 includes OR circuits 14a and 14b.

The OR circuit 14a includes a first terminal, a second terminal, and an output terminal. The signal PEI is input to the first terminal. The signal PRE is input to the second terminal. The OR circuit 14a performs a logical sum (OR) operation of the signals PEI and PRE. The OR circuit is also called a logical sum operation circuit. Then, the OR circuit 14a outputs the signal generated by the operation from the output terminal to the driving buffer circuit 15.

The OR circuit 14b includes a first terminal, a second terminal, and an output terminal. The signal NEI is input to the first terminal. The signal NRE is input to the second terminal. The OR circuit 14b performs an OR operation of the signals NEI and NRE. Then, the OR circuit 14b outputs the signal generated by the operation from the output terminal to the driving buffer circuit 15.

With the above configuration, the addition circuit 14 outputs the signal obtained by adding the signals PEI and PRE and the signal obtained by adding the signals NEI and NRE to the driving buffer circuit 15.

The driving buffer circuit 15 includes buffers 15a and 15b.

The buffer 15a receives a signal obtained by adding the signals PEI and PRE from the addition circuit 14. The buffer 15a generates, for example, a signal PE obtained by forming the signal into a rectangular wave. Then, the buffer 15aoutputs the signal PE to one end of the coil 2a of the isolation element 2.

The buffer 15b receives a signal obtained by adding the signals NEI and NRE from the addition circuit 14. The buffer 15b generates, for example, a signal NE obtained by forming the signal into a rectangular wave. Then, the buffer 15b outputs the signal NE to another end of the coil 2a of the isolation element 2.

### 1.1.3 Configuration of Secondary Circuit

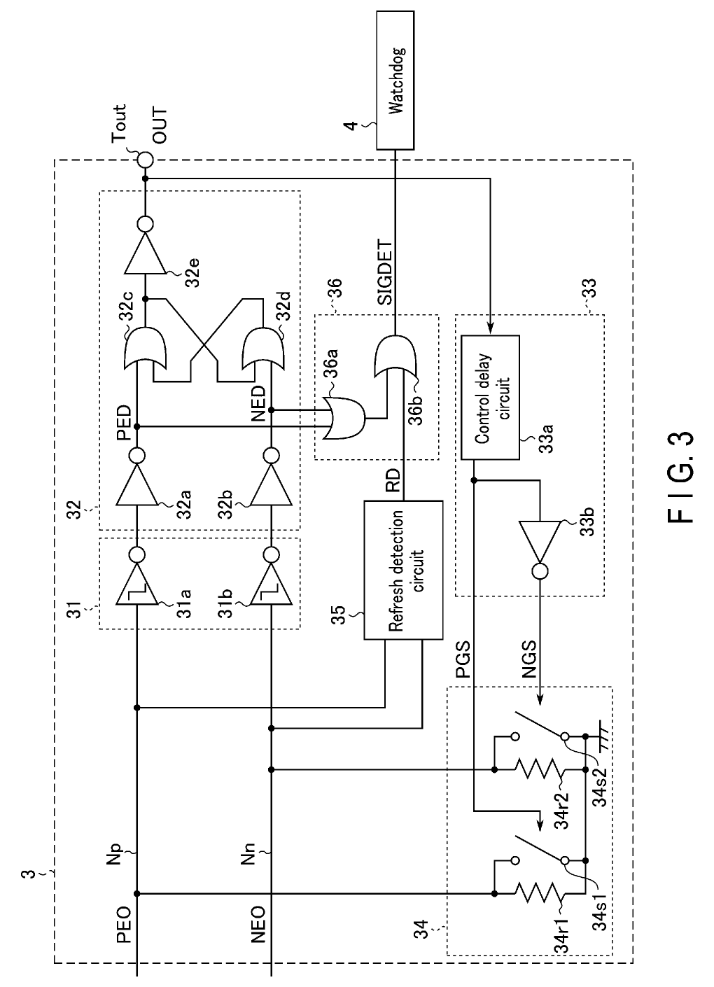

The configuration of the secondary circuit 3 will be described with reference to FIG. 3. FIG. 3 is a circuit diagram illustrating an example of a configuration of a secondary circuit of the digital isolator according to the embodiment.

The secondary circuit 3 includes an inverter circuit 31, a latch circuit 32, a control circuit 33, a switch circuit 34, a refresh detection circuit 35, and a pulse generation circuit 36.

The inverter circuit 31 includes inverters 31a and 31b.

The inverter 31a is coupled to the node Np. The signal PEO is input to the node Np. The inverter 31a generates a signal obtained by inverting the signal PEO. Then, the inverter 31a outputs the generated signal to the latch circuit 32.

The inverter 31b is coupled to the node Nn. The signal NEO is input to the node Nn. The inverter 31b generates a signal obtained by inverting the signal NEO. Then, the inverter 31b outputs the generated signal to the latch circuit 32.

The latch circuit 32 includes inverters 32a, 32b, and 32e, and OR circuits 32c and 32d.

The signal output from the inverter 31a is input to the inverter 32a. The inverter 32a generates a signal PED obtained by inverting the signal. Then, the inverter 32a outputs the signal PED to the OR circuit 32c.

The signal output from the inverter 31b is input to the inverter 32b. The inverter 32b generates a signal NED obtained by inverting the signal. Then, the inverter 32b outputs the signal NED to the OR circuit 32d.

The OR circuits 32c and 32d each include a first terminal, a second terminal, and an output terminal. The signal PED is input to the first terminal of the OR circuit 32c. The second terminal of the OR circuit 32c is coupled to the output terminal of the OR circuit 32d. The output terminal of the OR circuit 32c is coupled to the second terminal of the OR circuit 32d. The signal NED is input to the first terminal of the OR circuit 32d.

With the above configuration, the OR circuit 32c performs an OR operation of the signal PED and the signal output from the output terminal of the OR circuit 32d. Then, the OR circuit 32c outputs the signal generated by the operation from the output terminal to the second terminal of the OR circuit 32d and the inverter 32e.

In addition, the OR circuit 32d performs an OR operation of the signal NED and the signal output from the output terminal of the OR circuit 32c. Then, the OR circuit 32d outputs the signal generated by the operation from the output terminal to the second terminal of the OR circuit 32c.

The signal output from the OR circuit 32c is input to the inverter 32e. The inverter 32e generates a signal obtained by inverting the signal as the signal OUT. Then, the inverter 32e outputs the signal OUT to the terminal Tout.

With the above configuration, the latch circuit 32 latches data using a pulse of a signal corresponding to the signal PEO and a pulse of a signal corresponding to the signal NEO. Further, the latch circuit 32 outputs a signal OUT corresponding to the data to the terminal Tout.

The control circuit 33 includes a control delay circuit 33a and an inverter 33b.

The signal OUT is input to the control delay circuit 33a. The control delay circuit 33a generates a signal PGS obtained by delaying the signal OUT. Then, the control delay circuit 33a outputs the signal PGS to the inverter 33b and the switch circuit 34. The signal PGS is also referred to as a control signal.

The signal PGS is input to the inverter 33b. The inverter 33b generates a signal NGS obtained by inverting the signal PGS. Then, the inverter 33b outputs the signal NGS to the switch circuit 34. The signal NGS is also referred to as a control signal.

With the above configuration, the control circuit 33 is configured to control the switch circuit 34 described later by the signals PGS and NGS generated using the signal OUT.

The switch circuit 34 includes resistors 34r1 and 34r2 and switch elements 34s1 and 34s2.

One end of the resistor 34r1 is coupled to the node Np. Another end of the resistor 34r1 is grounded. That is, the potential at another end of the resistor 34r1 is set to the ground potential. Hereinafter, the ground potential is also referred to as a reference potential.

One end of the resistor 34r2 is coupled to the node Nn. Another end of the resistor 34r2 is grounded similarly to the resistor 34r1.

The switch element 34s1 is an element that is turned on or off by the signal PGS. The switch element 34s1 is turned on, for example, in a case where the signal PGS is at the “H” level. In addition, the switch element 34s1 is turned off, for example, in a case where the signal PGS is at the “L” level. One end of the switch element 34s1 is coupled to the node Np similarly to the one end of the resistor 34r1. Another end of the switch element 34s1 is coupled to another end of the resistor 34r1. Accordingly, another end of the switch element 34s1 is grounded similarly to another end of the resistor 34r1.

A switch element 34s2 is an element that is turned on or off by the signal NGS. The switch element 34s2 is turned on, for example, in a case where the signal NGS is at the “H” level. In addition, the switch element 34s2 is turned off, for example, in a case where the signal NGS is at the “L” level. As described above, since the signal NGS is an inverted signal of the signal PGS, the state (ON state or OFF state) of the switch element 34s2 is inverted with respect to the state of the switch element 34s1. One end of the switch element 34s2 is coupled to the node Nn similarly to the one end of the resistor 34r2. Another end of the switch element 34s2 is coupled to another end of the resistor 34r2. As a result, another end of the switch element 34s2 is grounded similarly to another end of the resistor 34r2.

With the above configuration, the switch circuit 34 switches a conduction state between the reference potential and the first output terminal of the isolation element 2. When the switch element 34s1 of the switch circuit 34 is turned on by the control of the control circuit 33, the first output terminal of the isolation element 2 is grounded via the switch element 34s1.

In addition, the switch circuit 34 switches a conduction state between the reference potential and the second output terminal of the isolation element 2. When the switch element 34s2 of the switch circuit 34 is turned on by the control of the control circuit 33, the second output terminal of the isolation element 2 is grounded via the switch element 34s2.

The refresh detection circuit 35 is coupled to the nodes Np and Nn. Accordingly, the signals PEO and NEO are input to the refresh detection circuit 35. The refresh detection circuit 35 generates a signal RD using the signals PEO and NEO. Although the configuration of the refresh detection circuit 35 and the signal RD will be described later in more detail, the signal RD corresponds to the refresh signal REF generated by the refresh timing signal generation circuit 13a of the primary circuit 1. Then, the refresh detection circuit 35 outputs the signal RD to the pulse generation circuit 36.

The pulse generation circuit 36 includes OR circuits 36a and 36b.

The OR circuit 36a includes a first terminal, a second terminal, and an output terminal. The signal PED is input from the latch circuit 32 to the first terminal. The signal NED is input from the latch circuit 32 to the second terminal. The OR circuit 36a performs an OR operation of the signals PED and NED. Then, the OR circuit 36a outputs a signal generated by the operation from the output terminal to the OR circuit 36b.

The OR circuit 36b includes a first terminal, a second terminal, and an output terminal. A signal output from the OR circuit 36a is input to the first terminal. The signal RD is input to the second terminal. The OR circuit 36b performs an OR operation of the signal RD and the signal output from the OR circuit 36a. Then, the OR circuit 36b outputs the signal SIGDET generated by the operation from the output terminal to the watchdog 4.

The signal SIGDET generated by the above configuration and the configuration of the refresh detection circuit 35 to be described later is a signal obtained by adding the signals PED and NED corresponding to the signals PEO and NEO and the signal RD corresponding to the signal REF. The pulse generation circuit 36 outputs such a signal SIGDET to the watchdog 4, so that the watchdog 4 can detect whether the primary circuit 1 is normally operating. The watchdog 4 determines that the primary circuit 1 is normally operating, for example, in a case where an interval of the pulses of the signal SIGDET is a predetermined period. In addition, for example, in a case where there is no pulse of the signal SIGDET for a predetermined period, the watchdog 4 determines that the primary circuit 1 does not normally operate. As a result, the watchdog 4 detects the loss of the power supply of the primary circuit 1.

### 1.1.4 Configuration of Refresh Detection Circuit

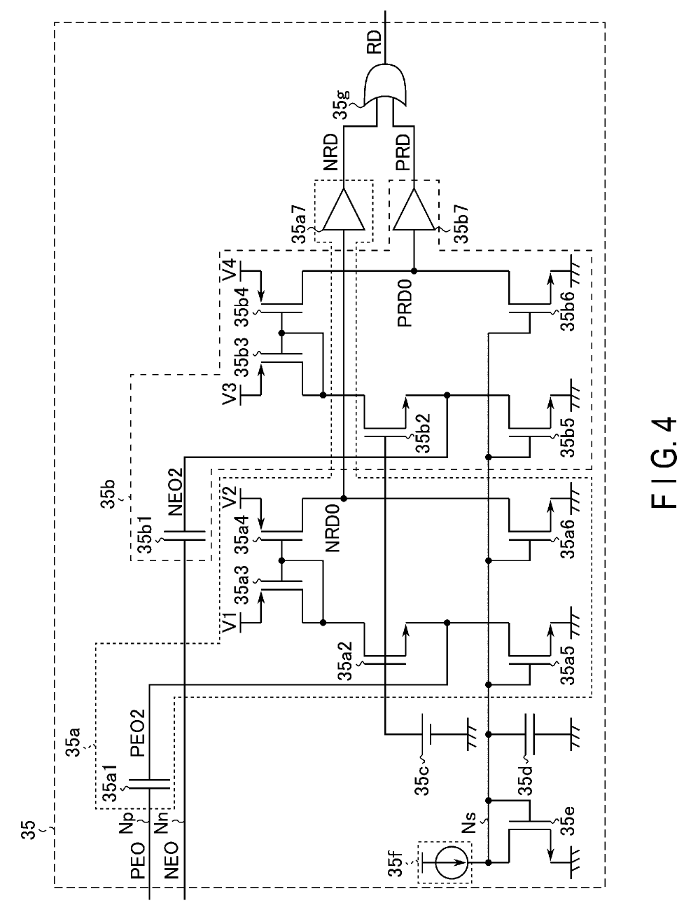

A configuration of the refresh detection circuit 35 will be described with reference to FIG. 4. FIG. 4 is a circuit diagram illustrating an example of a configuration of a refresh detection circuit of the digital isolator according to the embodiment.

Refresh detection circuit 35 includes detection portions 35a and 35b, a voltage source 35c, a capacitor 35d, a switch element 35e, a power supply 35f, and an OR circuit 35g. The switch element 35e is an N-type metal oxide semiconductor field effect transistor (MOSFET). The power supply 35f includes, for example, a constant current source to which a voltage is applied.

The detection portion 35a includes a capacitor 35a1, switch elements 35a2, 35a3, 35a4, 35a5, and 35a6, and a buffer 35a7. The switch elements 35a2, 35a5, and 35a6 are N-type MOSFETs. The switch elements 35a3 and 35a4 are P-type MOSFETs.

One end of the capacitor 35a1 is coupled to the node Np. As a result, the signal PEO is input to the one end of the capacitor 35a1. A signal PEO2 corresponding to the signal PEO is output from another end of the capacitor 35a1.

One end of the switch element 35a2 is coupled to another end of the capacitor 35a1. A gate of the switch element 35a2 is coupled to a terminal on the positive electrode side of the voltage source 35c. A terminal on the negative electrode side of the voltage source 35c is grounded.

A voltage V1 is applied to one end of the switch element 35a3. The voltage V1 is, for example, a constant voltage. Another end and a gate of the switch element 35a3 are coupled to another end of the switch element 35a2.

A voltage V2 is applied to one end of the switch element 35a4. The voltage V2 is, for example, a constant voltage. A gate of the switch element 35a4 is coupled to another end and the gate of the switch element 35a3. The potential at another end of the switch element 35a4 is a signal NRD0.

One end of the switch element 35a5 is coupled to another end of the capacitor 35a1 and the one end of the switch element 35a2. Another end of the switch element 35a5 is grounded. A gate of the switch element 35a5 is coupled to the node Ns. Power is applied from the power supply 35f to the node Ns.

One end of the switch element 35a6 is coupled to another end of the switch element 35a4. A gate of the switch element 35a6 is coupled to the node Ns. Another end of the switch element 35a6 is grounded.

The buffer 35a7 is coupled to another end of the switch element 35a4 and the one end of the switch element 35a6. The buffer 35a7 generates a signal NRD obtained by forming the signal NRD0 into a rectangular wave. Then, the buffer 35a7 outputs the signal NRD to the OR circuit 35g.

One end and a gate of the switch element 35e are coupled to the node Ns. Another end of the switch element 35e is grounded.

In the above configuration, the switch elements 35a3 and 35a4 configure a current mirror circuit. In addition, the switch elements 35a5 and 35a6 function as a sink circuit for a current flowing through a current mirror circuit including the switch elements 35a3 and 35a4. Then, the switch element 35a2 controls a current flowing through the switch element 35a3. More specifically, the switch element 35a2 is turned on or off based on a potential difference between the gate of the switch element 35a2 and one end (source) of the switch element 35a2. While the switch element 35a2 is in the on state, a current flows through the switch element 35a3. With the configuration of the current mirror circuit, a current flows through the switch element 35a4. In addition, while the switch element 35a2 is in the off state, the current flowing through the switch element 35a3 is stopped. As a result, the current flowing through the switch element 35a4 is also stopped.

The sizes of the switch elements 35a3 and 35a4 are set such that the current flowing through the switch element 35a4 is larger than the sink current of the switch element 35a6 while the switch element 35a2 is in the on state. The size of the switch element is, for example, a gate length and a channel width of the switch element.

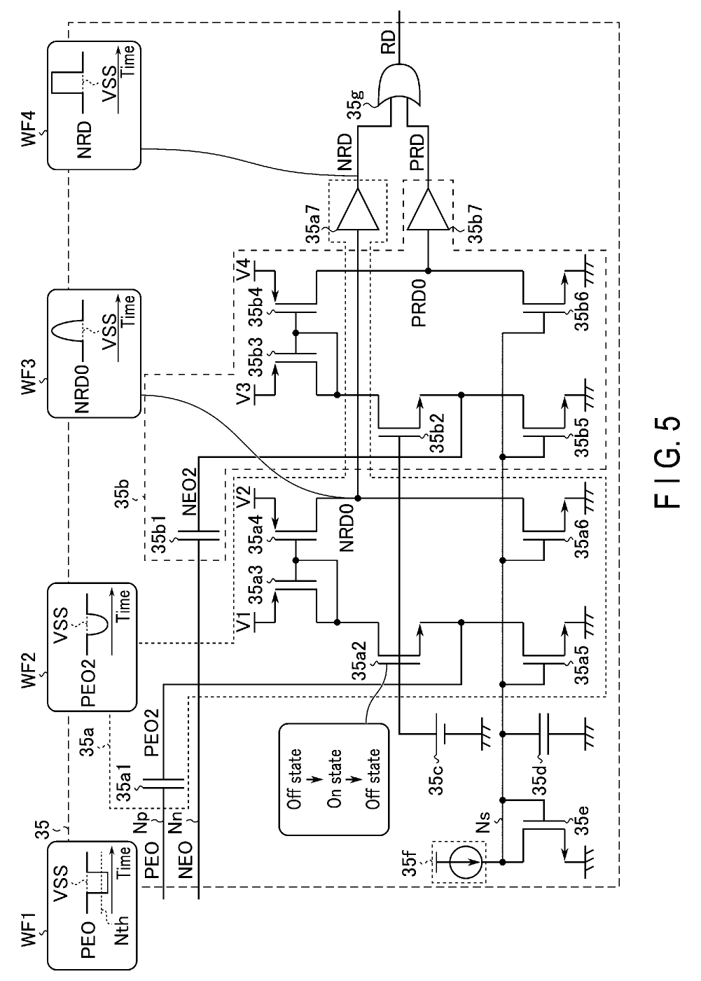

In addition, the detection portion 35a functions as a negative potential edge detection circuit together with the voltage source 35c, the capacitor 35d, the switch element 35e, and the power supply 35f. The negative potential edge detection circuit will be supplemented below with reference to FIG. 5. FIG. 5 is a circuit diagram illustrating an example of detection of a negative potential pulse by the refresh detection circuit of the digital isolator according to the embodiment. In FIG. 5, waveforms of the signals PEO, PEO2, NRD0, and NRD are indicated by waveforms WF1, WF2, WF3, and WF4, respectively. Hereinafter, the reference potential is referred to as a potential VSS.

Although the operation will be described later, the pulse of the signal PEO as indicated by the waveform WF1 is input to the secondary circuit 3 in correspondence with the pulse of the signal NRE which is the refresh signal. Such a pulse of the signal PEO has, for example, a negative potential lower than the reference potential. Hereinafter, for each signal, a pulse having a potential lower than the reference potential of the signal is also simply referred to as a negative potential pulse. For each signal, a pulse having a potential higher than the reference potential of the signal is also simply referred to as a positive potential pulse.

At this time, the waveform of the signal PEO2 becomes a waveform (valley waveform) falling to a negative potential with respect to the potential VSS due to AC (alternating current) coupling of the capacitor 35a1 as illustrated in the waveform WF2, for example.

The switch element 35a2 is configured to be turned on, for example, in a case where the signal PEO2 is equal to or less than a predetermined negative potential. In addition, the switch element 35a2 is configured to be turned off, for example, in a case where the signal PEO2 is higher than the potential. The potential is the potential of the signal PEO2 in a case where the signal PEO is equal to or less than a potential Nth. The potential Nth is, for example, a potential lower than the potential VSS.

With the above configuration, for example, the switch element 35a2 changes from the off state to the on state in response to a decrease in the signal PEO from the potential VSS to the potential Nth or less. As a result, the current flowing through the switch elements 35a3 and 35a4 increases. In addition, the switch element 35a2 changes from the on state to the off state in response to an increase in the signal PEO2 from the negative potential to the potential VSS. As a result, the current flowing through the switch elements 35a3 and 35a4 is reduced. As described above, in correspondence to the waveform of the signal PEO2 falling into the negative potential, the waveform of the signal NRD0 rises to the positive potential with respect to the potential VSS (chevron waveform), for example, as illustrated in the waveform WF3.

In addition, the signal NRD is formed into a rectangular wave having a positive potential with respect to the potential VSS as indicated by the waveform WF4 by forming a waveform by the buffer 35a7.

As described above, the negative potential edge detection circuit including the detection portion 35a can detect, by the signal NRD, that the negative potential pulse of the signal PEO is input to the secondary circuit 3.

Returning to FIG. 4, the configuration of the refresh detection circuit 35 will be described below.

The detection portion 35b includes a capacitor 35b1, switch elements 35b2, 35b3, 35b4, 35b5, and 35b6, and a buffer 35b7. The switch elements 35b2, 35b5, and 35b6 are N-type MOSFETs. The switch elements 35b3 and 35b4 are P-type MOSFETs.

A capacitor 35b1, switch elements 35b2, 35b3, 35b4, 35b5, and 35b6, and a buffer 35b7 correspond to the capacitor 35a1, the switch elements 35a2, 35a3, 35a4, 35a5, and 35a6, and the buffer 35a7 of the detection portion 35a, respectively. Hereinafter, regarding the configuration of the capacitor 35b1, the switch elements 35b2, 35b3, 35b4, 35b5, and 35b6, and the buffer 35b7, a description of the same configuration as the configuration of the detection portion 35a will be omitted, and differences from the configuration of the detection portion 35a will be mainly described.

One end of the capacitor 35b1 is coupled to the node Nn. As a result, the signal NEO is input to the one end of the capacitor 35b1. A signal NEO2 corresponding to the signal NEO is output from another end of the capacitor 35b1.

Similarly to the gate of the switch element 35a2, a gate of the switch element 35b2 is coupled to the terminal on the positive electrode side of the voltage source 35c.

A gate of each of the switch elements 35b5 and 35b6 is coupled to the node Ns, similarly to the gate of each of the switch elements 35a5 and 35a6.

The signal PRD0 is output from another end of the switch element 35b4.

The buffer 35b7 generates a signal PRD obtained by forming the signal PRD0 into a rectangular wave. Then, the buffer 35b7 outputs the signal PRD to the OR circuit 35g.

Similarly to the detection portion 35a, the detection portion 35b functions as a negative potential edge detection circuit together with the voltage source 35c, the capacitor 35d, the switch element 35e, and the power supply 35f. The negative potential edge detection circuit can detect that the negative potential pulse of the signal NEO is input to the secondary circuit 3 by the signal PRD similarly to the negative potential edge detection circuit including the detection portion 35a except that the signals NEO, NEO2, PRD0, and PRD are used instead of the signals PEO, PEO2, NRD0, and NRD.

The OR circuit 35g includes a first terminal, a second terminal, and an output terminal. The signals NRD and PRD are input to the first terminal and the second terminal. The OR circuit 35g performs an OR operation of the signals NRD and PRD. That is, the OR circuit 35g generates a signal RD obtained by adding the signals NRD and PRD. Then, the OR circuit 35g outputs the signal RD from the output terminal to the pulse generation circuit 36.

As described above, the signal RD is a signal obtained by adding the negative potential pulse of the signal PEO and the negative potential pulse of the signal NEO. Thus, the signal RD is also referred to as a negative potential detection signal.

### 1.2Operation

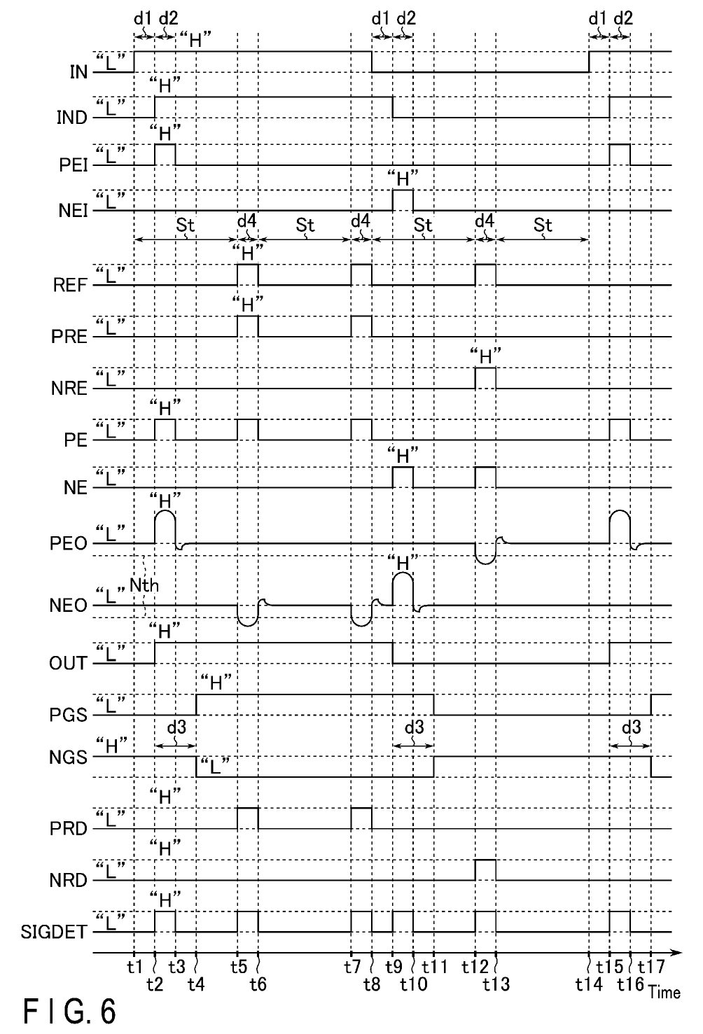

Next, an example of an operation using the digital isolator 100 according to the embodiment will be described with reference to FIG. 6. FIG. 6 is a timing chart illustrating an example of the operation of the digital isolator according to the embodiment. FIG. 6 illustrates signals IN, IND, PEI, NEI, REF, PRE, NRE, PE, NE, PEO, NEO, OUT, PGS, NGS, PRD, NRD, and SIGDET.

At time t1, the signal IN input to the terminal Tin changes from the “L” level to the “H” level.

At time t2, the input delay circuit 11 changes the signal IND from the “L” level to the “H” level based on the signal IN. The time t2 is a time when a period d1 has elapsed from the time t1. The period d1 is a signal delay period by the input delay circuit 11.

The edge detection circuit 12 detects an edge of the first polarity of the signal IND. Then, the edge detection circuit 12 outputs the positive potential pulse of the signal PEI to the addition circuit 14 according to the edge of the first polarity. That is, the edge detection circuit 12 changes the signal PEI from the “L” level to the “H” level. The edge detection circuit 12 sets the signal PEI to the “H” level only in a period d2. That is, a width of the positive potential pulse of the signal PEI is the period d2.

In addition, the driving buffer circuit 15 transmits the positive potential pulse of the signal PE having the “H” level to the isolation element 2 based on the signal PEI. In addition, a positive potential pulse of the signal PEO having the “H” level is input to the secondary circuit 3 by the isolation element 2. The signal NEO is set to the “L” level, for example. The “L” level of the signals PEO and NEO has a potential substantially equivalent to the potential VSS. The pulse widths of the signals PE and PEO are the period d2.

Further, the secondary circuit 3 changes the signal OUT from the “L” level to the “H” level based on the signal PEO. As a result, the signal OUT at the “H” level is output from the terminal Tout to the outside of the digital isolator 100.

At this time, since the signals PEO and NEO have potentials substantially equal to or higher than the potential VSS, the pulse of the signal RD is not generated in the refresh detection circuit 35 of the secondary circuit 3. That is, the signal RD is maintained at the “L” level. Furthermore, the pulse generation circuit 36 outputs a positive potential pulse of the signal SIGDET corresponding to the positive potential pulse of the signal PEO to the watchdog 4.

At time t3, the pulse of the signal PEI, the pulse of the signal PE, the pulse of the signal PEO, and the pulse of the signal SIGDET fall. The time t3 is a time when a periodd2 has elapsed from the time t2.

At time t4, the control circuit 33 changes the signal PGS from the “L” level to the “H” level. In addition, the control circuit 33 changes the signal NGS obtained by inverting the signal PGS from the “H” level to the “L” level. A period d3 between the timest2 and t4 is a delay period of the signal OUT by the control circuit 33. With the above operation, the switch element 34s1 is changed from the off state to the on state. In addition, the switch element 34s2 is changed from the on state to the off state.

At time t5, the refresh timing signal generation circuit 13a of the primary circuit 1 generates a positive potential pulse of the signal REF. That is, the refresh timing signal generation circuit 13a generates a positive potential pulse of the signal REF by detecting that the signal IN does not change for a preset period St from the timet1. The width of the pulse of the signal REF is a period d4. Then, the refresh circuit 13 outputs the positive potential pulse of the signal PRE to the addition circuit 14 based on the signals REF and IND. Further, the primary circuit 1 transmits the positive potential pulse of the signal PE to the isolation element 2 based on the positive potential pulse of the signal PRE. Since the signal NRE is maintained at the “L” level, the signal NE is set to the “L” level.

At this time, since the switch element 34s1 is in the on-state as described above, even if the signal PE at the “H” level is transmitted to the isolation element 2, the signal PEO is substantially equal to the potential VSS. On the other hand, since the switch element 34s2 is in the off-state as described above, a negative potential pulse of the signal NEO is generated due to the signal PEO being substantially equal to the potential VSS. The negative potential pulse of the signal NEO has a potential equal to or lower than the potential Nth. The negative potential pulse of the signal NEO is set to a negative potential for a period substantially equal to the period d4, for example.

With the above operation, in the refresh detection circuit 35, the negative potential edge detection circuit including the detection portion 35b outputs the positive potential pulse of the signal PRD to the OR circuit 35g based on the negative potential pulse of the signal NEO. In addition, the refresh detection circuit 35 outputs the positive potential pulse of the signal RD corresponding to the positive potential pulse of the signal PRD to the pulse generation circuit 36. Then, the pulse generation circuit 36 outputs a positive potential pulse of the signal SIGDET generated based on the positive potential pulse of the signal RD to the watchdog 4.

At time t6, the pulse of the signal REF, the pulse of the signal PRE, the pulse of the signal PE, the pulse of the signal PRD, and the pulse of the signal SIGDET fall. In addition, the potential of the signal NEO rises to, for example, the potential VSS or more. Note that, at this time, the potential of the signal NEO can reach a potential higher than the potential VSS due to a jump of the potential accompanying recovery from the negative potential. Such a jump of the potential is also called unnecessary radiation. The time t6 is a time when a period d4 has elapsed from the time t5.

At time t7, the refresh timing signal generation circuit 13a generates a positive potential pulse of the signal REF, for example, by detecting that the signal IN does not change for a preset period St from time t6.

The operation at time t7 is similar to the operation at time t5.

At time t8, the pulse of the signal REF, the pulse of the signal PRE, the pulse of the signal PE, the pulse of the signal PRD, and the pulse of the signal SIGDET fall, similarly to the operation at time t6. In addition, the potential of the signal NEO rises to, for example, the potential VSS or more. At this time, the potential of the signal NEO can reach a potential higher than the potential VSS due to the jump of the potential accompanying recovery from the negative potential, similarly to the operation at the time t6.

The signal IN input to the terminal Tin changes from the “H” level to the “L” level.

At time t9, the input delay circuit 11 changes the signal IND from the “H” level to the “L” level based on the signal IN. The time t9 is a time when a period d1 has elapsed from the timet8.

The edge detection circuit 12 detects an edge of the second polarity of the signal IND. Then, the edge detection circuit 12 outputs the positive potential pulse of the signal NEI to the addition circuit 14 according to the edge of the second polarity. That is, the edge detection circuit 12 changes the signal NEI from the “L” level to the “H” level in the period d2.

In addition, the driving buffer circuit 15 transmits the positive potential pulse of the signal NE having the “H” level to the isolation element 2 based on the signal NEI. In addition, a positive potential pulse of the signal NEO having the “H” level is input to the secondary circuit 3 by the isolation element 2. The pulse widths of the signals NE and NEO are the period d2.

Further, the secondary circuit 3 changes the signal OUT from the “H” level to the “L” level based on the signal NEO. As a result, the signal OUT at the “L” level is output from the terminal Tout to the outside of the digital isolator 100.

At this time, the pulse of the signal RD is not generated for the same reason as the operation at the timet2. In addition, the pulse generation circuit 36 outputs a positive potential pulse of the signal SIGDET corresponding to the positive potential pulse of the signal NEO to the watchdog 4.

At time t10, the pulse of the signal NEI, the pulse of the signal NE, the pulse of the signal NEO, and the pulse of the signal SIGDET fall. The time t10 is a time when a period d2 has elapsed from the time t9.

At timet11, the control circuit 33 changes the signal PGS from the “H” level to the “L” level. In addition, the control circuit 33 changes the signal NGS obtained by inverting the signal PGS from the “L” level to the “H” level. The time t11 is a time when the period d3 has elapsed from the time t9. With the above operation, the switch element 34s1 is changed from the on state to the off state. In addition, the switch element 34s2 is changed from the off state to the on state.

At time t12, the refresh timing signal generation circuit 13a of the primary circuit 1 detects that the signal IN does not change for a period St from time t8, thereby generating a positive potential pulse of the signal REF. Then, the refresh circuit 13 outputs the positive potential pulse of the signal NRE to the addition circuit 14 based on the signals REF and IND. Further, the primary circuit 1 transmits the positive potential pulse of the signal NE to the isolation element 2 based on the positive potential pulse of the signal NRE. Since the signal PRE is maintained at the “L” level, the signal PE is set to the “L” level.

At this time, since the switch element 34s2 is in the on-state as described above, even if the signal NE at the “H” level is transmitted to the isolation element 2, the signal NEO is substantially equal to the potential VSS. On the other hand, since the switch element 34s1 is in the off-state as described above, a negative potential pulse of the signal PEO is generated due to the signal NEO being substantially equal to the potential VSS. The negative potential pulse of the signal PEO has a potential equal to or lower than the potential Nth, similarly to the negative potential pulse of the signal NEO. Similarly to the negative potential pulse of the signal NEO, the negative potential pulse of the signal PEO is set to a negative potential for a period substantially equal to the period d4, for example.

With the above operation, in refresh detection circuit 35, the negative potential edge detection circuit including the detection portion 35a outputs the positive potential pulse of signal NRD to the OR circuit 35g based on the negative potential pulse of the signal PEO. Further, the refresh detection circuit 35 outputs the positive potential pulse of signal RD corresponding to the positive potential pulse of signal NRD to the pulse generation circuit 36. Then, the pulse generation circuit 36 outputs a positive potential pulse of the signal SIGDET generated based on the positive potential pulse of the signal RD to the watchdog 4.

At time t13, the pulse of the signal REF, the pulse of the signal NRE, the pulse of the signal NE, the pulse of the signal NRD, and the pulse of the signal SIGDET fall. In addition, the potential of the signal PEO rises to, for example, the potential VSS or more. At this time, the potential of the signal PEO can reach a potential higher than the potential VSS due to the jump of the potential accompanying recovery from the negative potential, similarly to the change of the signal NEO at times t6 and t8. The time t13 is a time when a period d4 has elapsed from the time t12.

At time t14, the signal IN input to the terminal Tin changes from the “L” level to the “H” level again.

Since the operation from time t15 to time t17 is equivalent to the operation from the time t2 to the time t4, a description of this operation will be omitted.

As described above, the operation of the digital isolator 100 according to the embodiment ends.

With the above operation, the secondary circuit 3 of the digital isolator 100 according to the embodiment outputs the edge of the signal IND and the pulse of the signal SIGDET corresponding to the pulse of the signal REF to the watchdog 4. In addition, the watchdog 4 can detect whether the power supply of the primary circuit 1 is lost based on the signal SIGDET.

According to the embodiment, the reliability of the digital isolator 100 can be improved. This will be described below.

The digital isolator 100 according to the embodiment is an edge transmission type digital isolator. The digital isolator 100 includes a primary circuit 1, an isolation element 2, and a secondary circuit 3. The primary circuit 1 includes an edge detection circuit 12, a refresh circuit 13, and a driving buffer circuit 15. The secondary circuit 3 includes a latch circuit 32, a control circuit 33, a switch circuit 34, and a refresh detection circuit 35. The edge detection circuit 12 detects an edge of the signal IND according to the signal IN, and outputs a signal PEI generated using the edge of the first polarity of the signal IN and a signal NEI generated using the edge of the second polarity of the signal IN. The refresh circuit 13 generates the signal REF based on the signal IN, and outputs the signal PRE generated corresponding to the “H” level using the signal REF and the signal NRE generated corresponding to the “L” level using the signal REF. The driving buffer circuit 15 outputs the signal PE generated using the signals PEI and PRE and the signal NE generated using the signals NEI and NRE. The isolation element 2 receives the signals PE and NE on the primary side, outputs the signal PEO corresponding to the signal PE from the first output terminal on the secondary side, and outputs the signal NEO corresponding to the signal NE from the second output terminal on the secondary side. The latch circuit 32 latches data generated using the signals NEO and PEO, and outputs the signal OUT having the “H” level or the “L” level according to the data. The switch circuit 34 includes a switch element 34s1 that switches a conduction state between the reference potential and the first output terminal using the signal OUT, and a switch element 34s2 that switches a conduction state between the reference potential and the second output terminal. Using the signal OUT, the control circuit 33 turns on one of the switch elements 34s1 and 34s2 and turns off the other switch element. The refresh detection circuit 35 outputs a signal RD according to whether the signal PEO or NEO is equal to or lower than the potential Nth lower than the reference potential. With the above configuration, the secondary circuit 3 of the digital isolator 100 can detect whether the power supply of the primary circuit 1 is lost at the time of data transmission. As a result, the reliability of the digital isolator 100 can be improved.

To supplement, for example, when the signal IN is changed from the “L” level to the “H” level, a negative potential pulse corresponding to the refresh signal REF appears in the opposite phase to the signals PE and PEO in which the positive potential pulse is generated corresponding to the rising edge of the signal IN. That is, a negative potential pulse of the signal NEO is generated. Furthermore, for example, when the signal IN is changed from the “H” level to the “L” level, a negative potential pulse corresponding to the refresh signal REF appears in the opposite phase to the signals NE and NEO in which the positive potential pulse is generated corresponding to a falling edge of the signal IN. That is, a negative potential pulse of the signal PEO is generated. The rising edge and the falling edge of the signal IN are also referred to as data edges. In an embodiment, the secondary circuit 3 is configured to generate a signal SIGDET corresponding to a pulse corresponding to the data edge, a negative potential pulse of the signal PEO, and a negative potential pulse of the signal NEO. As described above, the secondary circuit 3 can output the signal SIGDET including the pulse corresponding to the pulse of the refresh signal REF generated in the primary circuit 1. Therefore, according to the embodiment, the secondary circuit 3 can detect whether the power supply of the primary circuit 1 is lost.

### 2 Modifications

Next, a digital isolator according to modifications will be described. Hereinafter, description of configurations equivalent to those of the embodiment will be omitted, and configurations different from those of the embodiment will be mainly described.

### 2.1 First Modification

The configuration of the refresh detection circuit is not limited to the configuration according to the embodiment. Hereinafter, the configuration and operation of a digital isolator according to a first modification will be described with respect to points different from the configuration and operation of the digital isolator according to the embodiment.

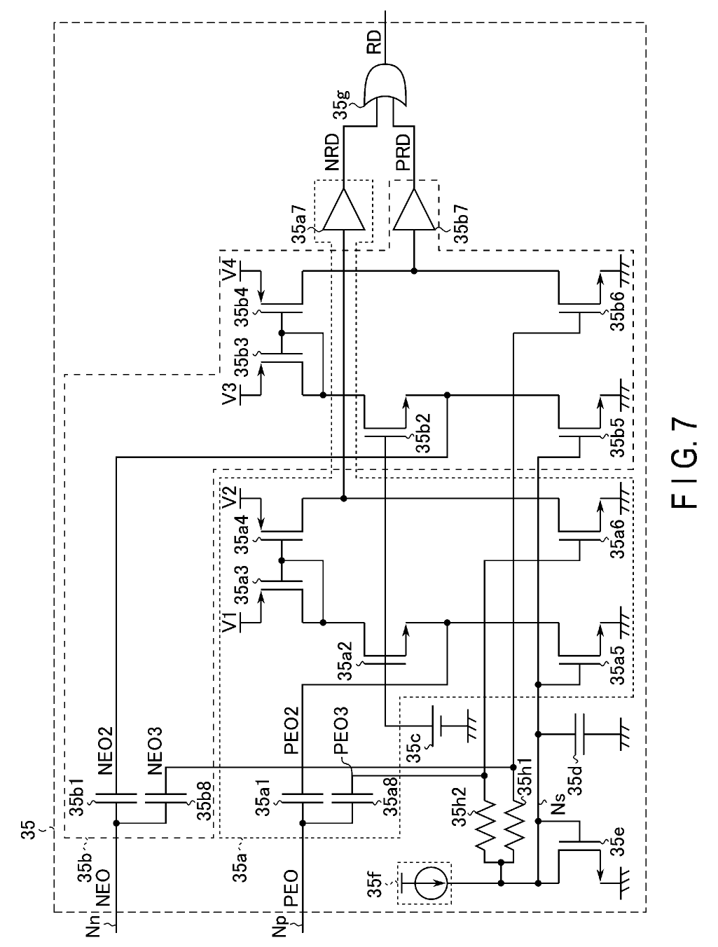

A configuration of a digital isolator 100 according to the first modification will be described with reference to FIG. 7. FIG. 7 is a circuit diagram illustrating an example of a configuration of a refresh detection circuit of a digital isolator according to the first modification.

The refresh detection circuit 35 according to the first modification further includes capacitors 35a8 and 35b8, and resistors 35h1 and 35h2.

The capacitor 35a8 is included in the detection portion 35a. One end of the capacitor 35a8 is coupled to the node Np. As a result, the capacitor 35a8 is coupled to the node Np in parallel with the capacitor 35a1. The signal PEO is input to the one end of the capacitor 35a8. Another end of the capacitor 35a8 is coupled to the resistor 35h2 and the gate of the switch element 35a6. A signal PEO3 corresponding to the signal PEO is output from another end of the capacitor 35a8.

The capacitor 35b8 is included in the detection portion 35b. One end of the capacitor 35b8 is coupled to the node Nn. As a result, the capacitor 35b8 is coupled to the node Nn in parallel with the capacitor 35b1. The signal NEO is input to the one end of the capacitor 35b8. Another end of the capacitor 35b8 is coupled to the resistor 35h1 and the gate of the switch element 35b6. A signal NEO3 corresponding to the signal NEO is output from another end of the capacitor 35b8.

One end of the resistor 35h1 is coupled to another end of the capacitor 35b8 and the gate of the switch element 35b6. Another end of the resistor 35h1 is coupled to the node Ns. Thus, in the first modification, the gate of the switch element 35b6 is coupled to the node Ns via the resistor 35h1. The resistor 35h1 is included in the negative potential edge detection circuit including the detection portion 35b.

One end of the resistor 35h2 is coupled to another end of the capacitor 35a8 and the gate of the switch element 35a6. Another end of the resistor 35h2 is coupled to the node Ns. Thus, in the first modification, the gate of the switch element 35a6 is coupled to the node Ns via the resistor 35h2. The resistor 35h2 is included in the negative potential edge detection circuit including the detection portion 35a.

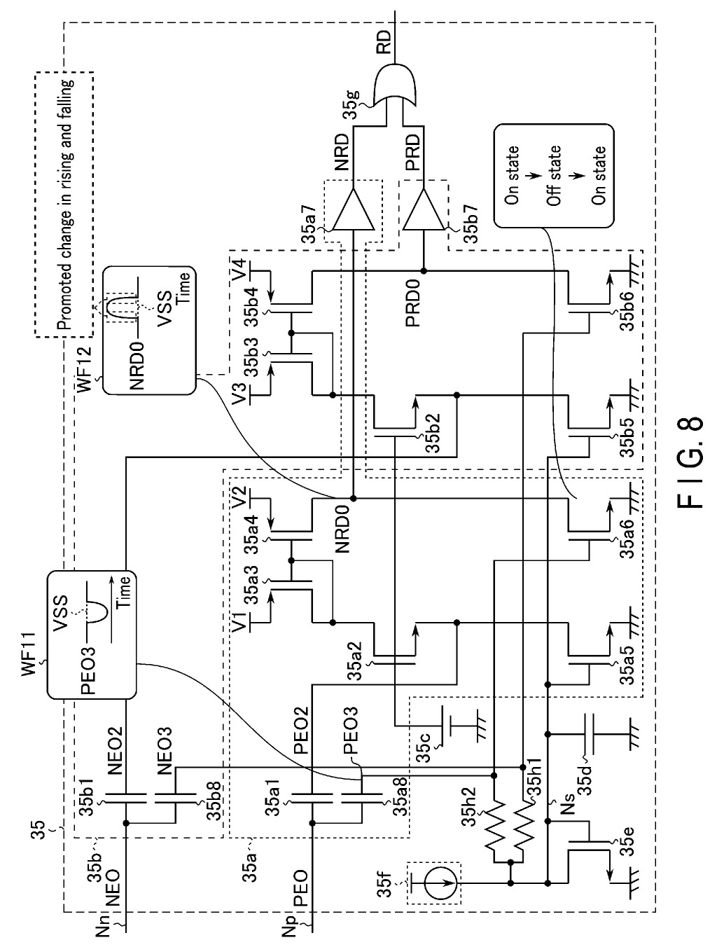

Hereinafter, an example of detection of the negative potential pulse by the negative potential edge detection circuit will be described with reference to FIG. 8 in terms of differences from the embodiment. FIG. 8 is a circuit diagram illustrating an example of detection of a negative potential pulse by the refresh detection circuit of the digital isolator according to the first modification. In FIG. 8, waveforms of the signals PEO3 and NRD0 are indicated by waveforms WF11 and WF12, respectively.

As described above, the resistor 35h2 is provided between the gate of the switch element 35a6 and the node Ns. As a result, the gate of the switch element 35a6 and the gates of the switch elements 35e and 35a5 are separated from each other in terms of AC.

Similarly to the embodiment, the negative potential pulse of the signal PEO is input to the secondary circuit 3 in correspondence with the pulse of the signal NRE which is the refresh signal. At this time, the waveform of the signal PEO3 becomes, for example, a waveform falling to a negative potential with respect to the potential VSS due to the AC coupling of the capacitor 35a8 as illustrated in the waveform WF11. As a result, the potential of the gate of the switch element 35a6 changes in conjunction with the signal PEO. In the first modification, the switch element 35a6 is configured to be turned off in a case where the signal PEO3 is equal to or less than a predetermined negative potential. In addition, the switch element 35a6 is configured to be turned on in a case where the signal PEO3 is higher than the potential. The potential is, for example, the potential of the signal PEO3 in a case where the signal PEO is equal to or less than the potential Nth.

With the above configuration, the switch element 35a6 changes to have a state opposite to that of the switch element 35a2, for example. As a result, the current flowing through the switch element 35a4 and the current flowing through the switch element 35a6 change in opposite phases (opposite). That is, in a case where the current flowing through the switch element 35a4 increases, the current flowing through the switch element 35a6 decreases. In a case where the current flowing through the switch element 35a4 decreases, the current flowing through the switch element 35a6 increases. As described above, the change in the potential of the signal NRD0 is accelerated. That is, in the signal NRD0, a change in rising and a change in falling are promoted as indicated by a waveform WF12. As a result, the detection sensitivity of the negative potential pulse of the signal PEO is improved. Accordingly, in the signal NRD, a rise change and a fall change are also promoted. Therefore, delay in detection of the negative potential pulse of the signal PEO is suppressed.

As described above, the negative potential edge detection circuit including the detection portion 35a in the first modification can improve the detection of the negative potential pulse of the signal PEO.

Note that the negative potential edge detection circuit including the detection portion 35b can detect, by the signal PRD, that the negative potential pulse of the signal NEO is input to the secondary circuit 3, similarly to the negative potential edge detection circuit including the detection portion 35a, except that the signals NEO, NEO2, NEO3, PRD0, and PRD are used instead of the signals PEO, PEO2, PEO3, NRD0, and NRD. Therefore, the negative potential edge detection circuit including the detection portion 35b can improve the detection of the negative potential pulse of the signal NEO for the same reason as the negative potential edge detection circuit including the detection portion 35a.

Since the operation of the digital isolator 100 according to the first modification can be substantially similar to the operation of the digital isolator according to the embodiment, the description thereof will be omitted.

Also in the first modification, the same effects as those of the embodiment are obtained.

Furthermore, according to the first modification, as described above, it is possible to suppress the delay in detection of the negative potential pulse of the signal PEO and the delay in detection of the negative potential pulse of the signal NEO. Accordingly, the detection sensitivity and the operation speed of the negative potential pulse can be improved.

### 2.2 Second Modification

The configuration of the refresh detection circuit is not limited to the configuration according to the embodiment and the first modification. Hereinafter, the configuration and operation of a digital isolator according to a second modification will be described with respect to points different from the configuration and operation of the digital isolator according to the first modification.

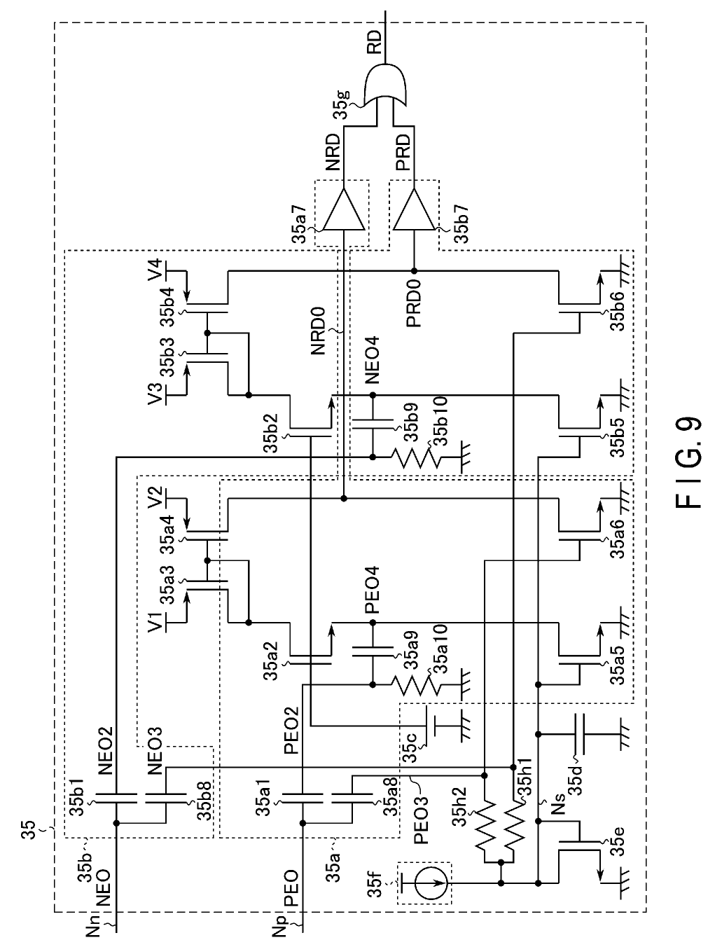

A configuration of a digital isolator 100 according to the second modification will be described with reference to FIG. 9. FIG. 9 is a circuit diagram illustrating an example of a configuration of a refresh detection circuit of a digital isolator according to a second modification.

The refresh detection circuit 35 according to the second modification further includes capacitors 35a9 and 35b9, and resistors 35a10 and 35b10.

The capacitor 35a9 and the resistor 35a10 are included in the detection portion 35a.

One end of the capacitor 35a9 is coupled to another end of the capacitor 35a1. Another end of the capacitor 35a9 is coupled to one end of each of the switch elements 35a2 and 35a5. A signal PEO4 is output from another end of the capacitor 35a9.

One end of the resistor 35a10 is coupled to another end of the capacitor 35a1 and the one end of the capacitor 35a9. Another end of the resistor 35a10 is grounded.

In the above configuration, the capacitor 35a9 and the resistor 35a10 function as a filter.

The capacitor 35b9 and the resistor 35b10 are included in the detection portion 35b.

One end of the capacitor 35b9 is coupled to another end of the capacitor 35b1. Another end of the capacitor 35b9 is coupled to one end of each of the switch elements 35b2 and 35b5. A signal NEO4 is output from another end of the capacitor 35b9.

One end of the resistor 35b10 is coupled to another end of the capacitor 35b1 and the one end of the capacitor 35b9. Another end of the resistor 35b10 is grounded.

In the above configuration, the capacitor 35b9 and the resistor 35b10 function as a filter.

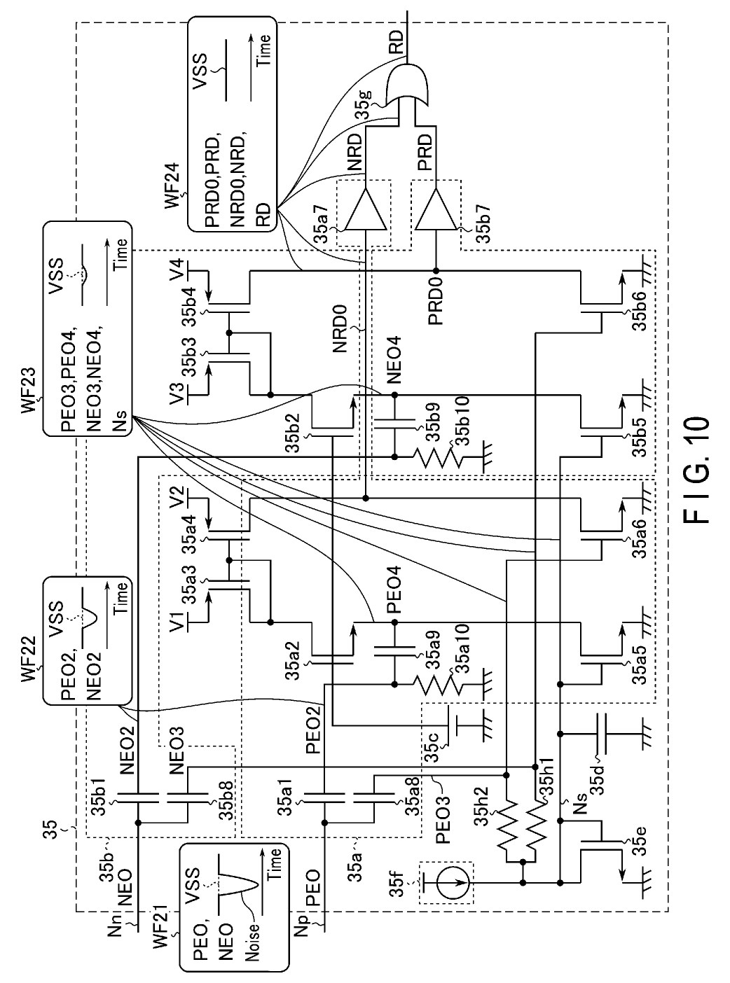

Hereinafter, removal of noise by the refresh detection circuit 35 when noise having a rapid potential change is applied to the signals NEO and PEO will be described with reference to FIG. 10. FIG. 10 is a circuit diagram illustrating an example of detection of a negative potential pulse by the refresh detection circuit of the digital isolator according to the second modification. In FIG. 10, waveforms of the signals PEO and NEO are indicated by a waveform WF21. In addition, waveforms of the signals PEO2 and NEO2 are indicated by a waveform WF22. In addition, waveforms of the signals PEO3, PEO4, NEO3, NEO4, and Ns are indicated by a waveform WF23. In addition, waveforms of the signals PRD0, PRD, NRD0, NRD, and RD are indicated by a waveform WF24.

For example, when a sudden potential difference between the potential supplied to the primary circuit 1 and the potential supplied to the secondary circuit 3 is applied, noise may be generated in the signals PEO and NEO. The noise may have a valley waveform that greatly attenuates to a negative potential as indicated by the waveform WF21.

Such noise has a lower slew rate of vibration with respect to the capacitor than the pulse of the signal PEO or NEO by the refresh signal. Therefore, the noise of the signal PEO becomes a signal PEO2 whose amplitude is attenuated by the capacitor 35b1 as indicated by the waveform WF22. As indicated by the waveform WF23, such a signal PEO2 becomes the signal PEO4 whose amplitude is further attenuated by a filter including the capacitor 35a9 and the resistor 35a10. Furthermore, by the filter including the capacitor 35d and the resistor 35h2, the noise of the signal PEO is, for example, the signal PEO3 with an attenuated amplitude, similarly to the noise of the signal PEO2, as illustrated in the waveform WF23. The changes of the signals NEO2, NEO3, and NEO4 with respect to the noise of the signal NEO are similar to the changes of the signals PEO2, PEO3, and PEO4.

With the above configuration, even in a case where the noise of the signal PEO as described above occurs, it is possible to suppress the occurrence of the noise of the signal NRD0 and the noise of the signal NRD output from another end of the switch element 35a4 as indicated by the waveform WF24. Furthermore, even in a case where noise of the signal NEO occurs, it is possible to suppress the occurrence of noise of the signal PRD0 output from another end of the switch element 35b4 and noise of the signal PRD as illustrated in the waveform WF24. Therefore, noise of the signal RD is also removed.

The second modification also achieves effects equivalent to those of the embodiment and the first modification.

Furthermore, according to the second modification, for example, even in a case where noise of the signals PEO and NEO as described above occurs due to destabilization or the like of the power supplies of the primary circuit 1 and the secondary circuit 3, it is possible to suppress the occurrence of noise in the refresh detection circuit 35 caused by these signals.

### 2.3 Third Modification

In the above-described embodiment, as described with reference to FIG. 6, unnecessary radiation occurs at times t6,t8, and t13. The secondary circuit 3 may have a configuration that suppresses the occurrence of such unnecessary radiation. Hereinafter, the configuration and operation of a digital isolator according to a third modification will be described with respect to points different from the configuration and operation of the digital isolator according to the embodiment.

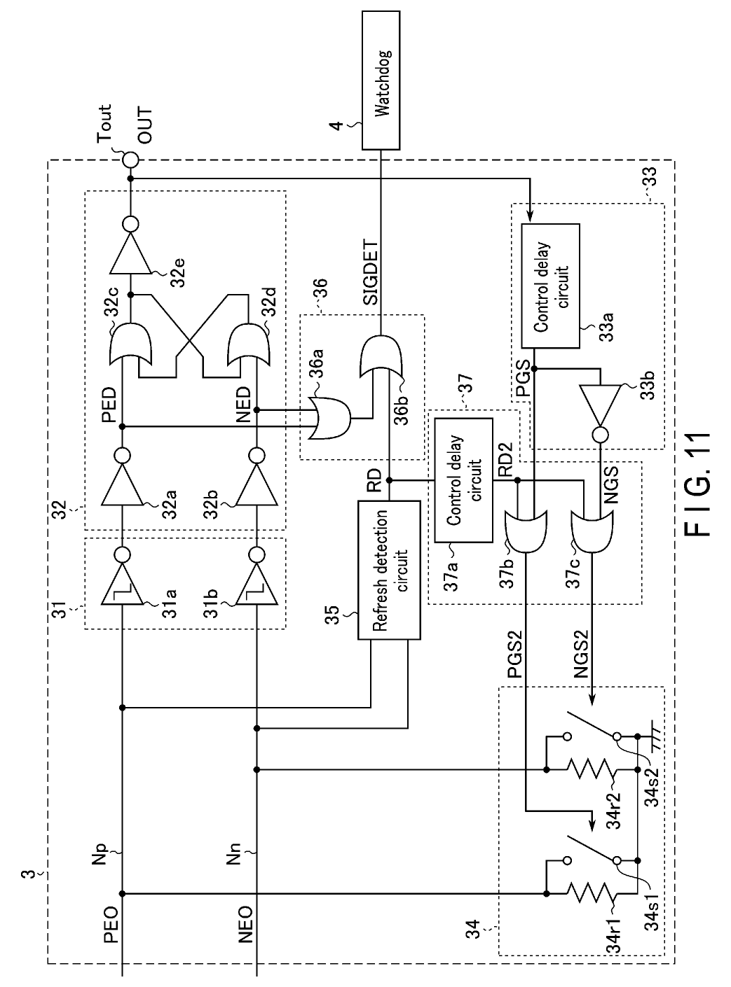

A configuration of a secondary circuit 3 of a digital isolator 100 according to a third modification will be described with reference to FIG. 11. FIG. 11 is a circuit diagram illustrating an example of a configuration of a secondary circuit of a digital isolator according to the third modification.

The secondary circuit 3 according to the third modification further includes a control circuit 37.

The control circuit 37 includes a control delay circuit 37a and OR circuits 37b and 37c.

The signal RD is input to the control delay circuit 37a. The control delay circuit 37a generates a signal RD2 obtained by delaying the signal RD. Then, the control delay circuit 37a outputs the signal RD2 to the OR circuits 37b and 37c. Note that the delay period by the control delay circuit 37a is, for example, substantially equal to the period d4 of the pulse of the signal REF.

The OR circuit 37b includes a first terminal, a second terminal, and an output terminal. The signal RD2 is input to the first terminal. A signal PGS is input from the control circuit 33 to the second terminal. The OR circuit 37bperforms an OR operation of the signals RD2 and PGS. Then, the OR circuit 37boutputs the signal PGS2 generated by the operation from the output terminal to the switch circuit 34.

The OR circuit 37c includes a first terminal, a second terminal, and an output terminal. The signal RD2 is input to the first terminal. A signal NGS is input from the control circuit 33 to the second terminal. The OR circuit 37c performs an OR operation of the signals RD2 and NGS. Then, the OR circuit 37c outputs the signal NGS2 generated by the operation from the output terminal to the switch circuit 34.

In the third modification, the switch element 34s1 is controlled by a signal PGS2 instead of the signal PGS. The switch element 34s2 is controlled by the signal NGS2 instead of the signal NGS.

With the above configuration, the control circuit 37 can suppress the occurrence of unnecessary radiation. More specifically, in a case where a negative potential pulse of the signal PEO is generated, the control delay circuit 37a outputs the delayed signal RD2 at the “H” level based on the pulses at the “H” level of the signals PRD and RD. Accordingly, the OR circuit 37b outputs the signal PGS2 at the “H” level based on the signal RD2 at the “H” level and the signal PGS at the “L” level. As described above, for example, immediately after the generation of the negative potential pulse, the switch element 34s1 is changed from the off state to the on state. As a result, since the node Np is grounded, the occurrence of unnecessary radiation due to the negative potential pulse of the signal PEO is suppressed.

In addition, even in a case where the negative potential pulse of the signal NEO is generated, the generation of unnecessary radiation caused by the negative potential pulse of the signal NEO is suppressed similarly to the case where the negative potential pulse of the signal PEO is generated, except that the OR circuit 37c and the switch element 34s2 operate instead of the OR circuit 37b and the switch element 34s1, and the signals NGS and NGS2 are used instead of the signals PGS and PGS2.

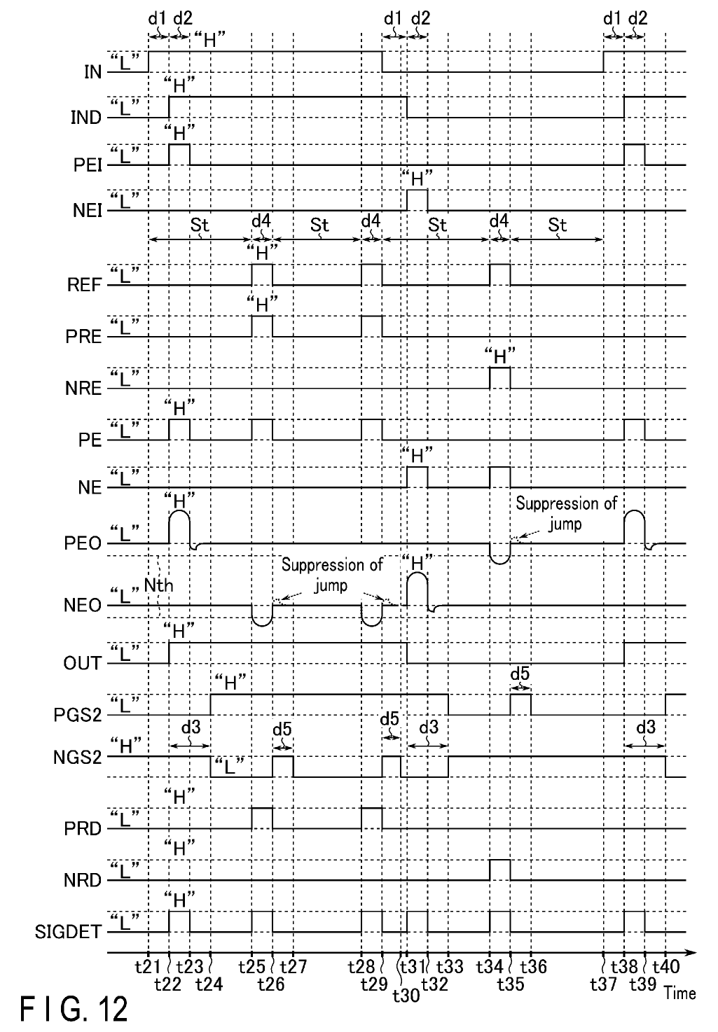

Next, an operation using the digital isolator 100 according to the third modification will be described with reference to FIG. 12. FIG. 12 is a timing chart illustrating an example of the operation of the digital isolator according to the third modification. FIG. 12 illustrates signals IN, IND, PEI, NEI, REF, PRE, NRE, PE, NE, PEO, NEO, OUT, PGS2, NGS2, PRD, NRD, and SIGDET.

Hereinafter, the operation of the digital isolator 100 according to the third modification will be mainly described in terms of differences from the operation of the digital isolator according to the embodiment.

The operation from time t21 to time t23 is similar to the operation from the time t1 to the time t3 of the embodiment.

At time t24, the signal PGS changes from the “L” level to the “H” level, similarly to the operation at the time t4 of the embodiment. The signal NGS is changed from the “H” level to the “L” level. As described above, the control circuit 37 changes the signal PGS2 from the “L” level to the “H” level. In addition, the control circuit 37 changes the signal NGS2 from the “H” level to the “L” level. With the above operation, similarly to the operation at the time t4 of the embodiment, the switch element 34s1 is changed from the off state to the on state. In addition, the switch element 34s2 is changed from the on state to the off state.

The operation at time t25 is similar to the operation at the time t5 of the embodiment.

At timet26, among the signals illustrated in FIG. 12, the signals excluding the signals NGS2 and NEO are similar to those at the time t6 of the embodiment. The control circuit 37 changes the signal NGS2 from the “L” level to the “H” level based on the negative potential pulse of the signal NEO from the timet25 to the time t26. That is, the control circuit 37 generates a pulse of the signal NGS2 by delaying the generation of the negative potential pulse by the period d4, for example. As a result, the switch element 34s2 is changed from the off state to the on state. As described above, for example, the node Nn is grounded, and the potential jump of the signal NEO is suppressed.

At time t27, the signal NGS2 is changed from the “H” level to the “L” level, and the pulse of the signal NGS2 is lost. As a result, the switch element 34s2 is changed from the on state to the off state. A period d5 of the pulse of the signal NGS2 from the timet26 to the time t27 may be substantially equivalent to the period d4.

The operation at time t28 is similar to the operation at the time t7 of the embodiment.

The operation at time t29 is similar to the operation at the time t8 of the embodiment except that the states of the signals NGS2 and NEO and the switch element 34s2 change similarly to the states of these signals and switch elements at the time t26.

At time t30, the states of the signals NGS2 and NEO and the switch element 34s2 change similarly to the states of these signals and the switch element at time t27.

The operation from timet31 to time t34 is similar to the operation from the time t9 to the timet12 of the embodiment.

At time t35, among the signals illustrated in FIG. 12, the signals excluding the signals PGS2 and PEO are similar to those at the time t13 of the embodiment. The control circuit 37 changes the signal PGS2 from the “L” level to the “H” level based on the negative potential pulse of the signal PEO from the time t34 to the time t35. That is, the control circuit 37 generates the pulse of the signal PGS2 by delaying the generation of the negative potential pulse by the period d4, for example. As a result, the switch element 34s1 is changed from the off state to the on state. As described above, for example, the node Np is grounded, and the jump of the potential of the signal PEO is suppressed.

At time t36, the signal PGS2 changes from the “H” level to the “L” level, and the pulse of the signal PGS2 is lost. As a result, the switch element 34s1 is changed from the on state to the off state. A period from the time t35 to the time t36 is the period d5.

The operation from time t37 to time t40 is similar to the operation from the timet14 to the time t17 of the embodiment.

As described above, the operation of the third modification ends.

The third modification also achieves effects equivalent to those of the embodiment.

Further, according to the third modification, it is possible to suppress the occurrence of unnecessary radiation caused by the negative potential pulses of the signals PEO and NEO. In addition, it is possible to suppress the occurrence of malfunction due to unnecessary radiation. To supplement, for example, erroneous detection of the data edge (edge of the signal IND) of the signal IN due to generation of unnecessary radiation in which the signal PEO or NEO reaches the “H” level is suppressed.

### 2.4 Fourth Modification

In the third modification described above, an example has been described in which the secondary circuit controls the switch element by the control circuit including the delay circuit and the two OR circuits, thereby suppressing the occurrence of unnecessary radiation. However, the present invention is not limited to this. The secondary circuit may suppress generation of unnecessary radiation by a delay circuit and a switch circuit including two switch elements.

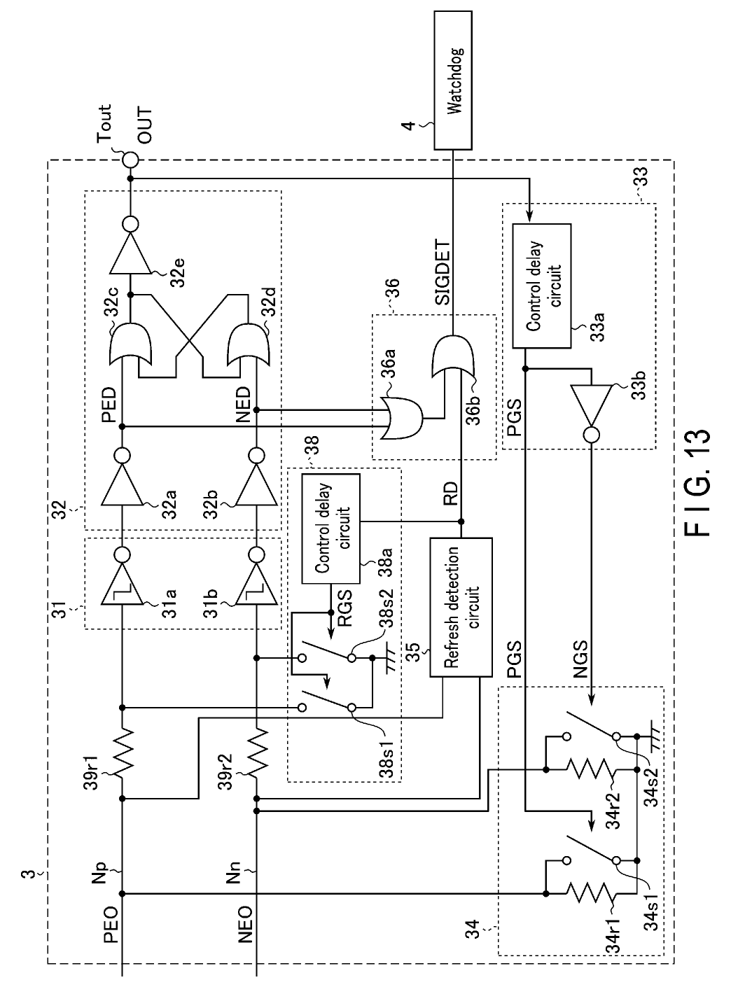

A configuration of a secondary circuit 3 of a digital isolator 100 according to a fourth modification will be described with reference to FIG. 13. FIG. 13 is a circuit diagram illustrating an example of a configuration of a secondary circuit of a digital isolator according to the fourth modification. Hereinafter, the configuration of the secondary circuit 3 according to the fourth modification will be described with respect to a configuration different from the configuration of the secondary circuit according to the embodiment.

The secondary circuit 3 according to the fourth modification further includes resistors 39r1 and 39r2 and a switch circuit 38.

One end of the resistor 39r1 is coupled to a node Np. Another end of the resistor 39r1 is coupled to an inverter 31a. With such a configuration, in the fourth modification, the inverter 31a is coupled to the node Np via the resistor 39r1.

One end of the resistor 39r2 is coupled to a node Nn. Another end of the resistor 39r2 is coupled to an inverter 31b. With such a configuration, in the fourth modification, the inverter 31b is coupled to the node Nn via the resistor 39r2.

The switch circuit 38 includes a control delay circuit 38a and switch elements 38s1 and 38s2.

The control delay circuit 38a receives a signal RD from a refresh detection circuit 35. The control delay circuit 38a generates a signal RGS obtained by delaying the signal RD. Then, the control delay circuit 38a outputs a signal RGS. Note that the delay period by the control delay circuit 38a is, for example, substantially equal to the period d4 of the pulse of the signal REF.

One end of the switch element 38s1 is coupled between another end of the resistor 39r1 and the inverter 31a. Another end of the switch element 38s1 is grounded.

One end of the switch element 38s2 is coupled between another end of the resistor 39r2 and the inverter 31b. Another end of the switch element 38s2 is grounded.

The switch elements 38s1 and 38s2 are elements that are turned on or off by the signal RGS. The switch elements 38s1 and 38s2 are turned on, for example, in a case where the signal RGS is at the “H” level. In addition, the switch elements 38s1 and 38s2 are turned off, for example, in a case where the signal RGS is at the “L” level.

With the above configuration, the switch circuit 38 functions as a shunt switch.

With the above configuration, the switch circuit 38 can suppress the occurrence of unnecessary radiation. More specifically, in a case where a negative potential pulse of the signal PEO or NEO occurs, the switch circuit 38 outputs a delayed signal RGS at the “H” level based on the pulse at the “H” level of the signal RD. As a result, the switch elements 38s1 and 38s2 are changed from the off state to the on state. Therefore, by grounding the nodes Np and Nn, the occurrence of unnecessary radiation caused by the negative potential pulse of the signal PEO or NEO is suppressed.

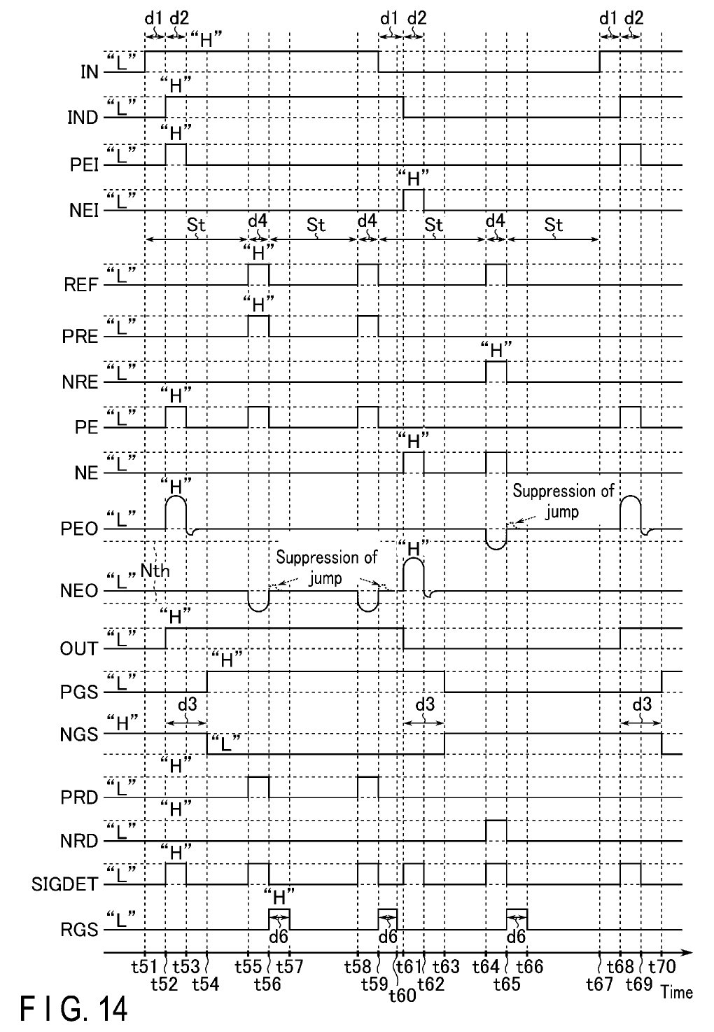

Next, an operation using the digital isolator 100 according to the fourth modification will be described with reference to FIG. 14. FIG. 14 is a timing chart illustrating an example of the operation of the digital isolator according to the fourth modification. FIG. 14 illustrates signals IN, IND, PEI, NEI, REF, PRE, NRE, PE, NE, PEO, NEO, OUT, PGS, NGS, PRD, NRD, SIGDET, and RGS.

Hereinafter, the operation of the digital isolator 100 according to the fourth modification will be mainly described in terms of differences from the operation of the digital isolator according to the embodiment.

The operation from time t51 to time t55 is similar to the operation from the time t1 to the time t5 of the embodiment.

At time t56, among the signals illustrated in FIG. 14, the signals excluding the signals RGS and NEO are similar to those at the time t6 of the embodiment. The switch circuit 38 changes the signal RGS from the “L” level to the “H” level based on the negative potential pulse of the signal NEO from the time t55 to the time t56. That is, the switch circuit 38 generates a pulse of the signal RGS by delaying the generation of the negative potential pulse by the period d4, for example. As a result, the switch elements 38s1 and 38s2 are changed from the off state to the on state. As described above, for example, the nodes Np and Nn are grounded, and the jump of the potential of the signal NEO is suppressed.

At time t57, the signal RGS is changed from the “H” level to the “L” level, and the pulse of the signal RGS is lost. As a result, the switch elements 38s1 and 38s2 are changed from the on state to the off state. A period d6 of the pulse of the signal RGS from the time t56 to the time t57 may be substantially equivalent to the period d4.

The operation at time t58 is similar to the operation at the time t7 of the embodiment.

The operation at time t59 is similar to the operation at the time t8 of the embodiment except that the signals RGS and NEO change similarly to these signals at the time t56.

At time t60, the states of the signals RGS and NEO and the switch elements 38s1 and 38s2 change similarly to the states of these signals and these switch elements at the timet57.

The operation from time t61 to time t64 is similar to the operation from the timet9 to the time t12 of the embodiment.

At time t65, among the signals illustrated in FIG. 14, the signals excluding the signals RGS and PEO are similar to those at the time t13 of the embodiment. The switch circuit 38 changes the signal RGS from the “L” level to the “H” level based on the negative potential pulse of the signal PEO from the timet64 to the time 65. That is, the switch circuit 38 generates a pulse of the signal RGS by delaying the generation of the negative potential pulse by the period d4, for example. As a result, the switch elements 38s1 and 38s2 are changed from the off state to the on state. As described above, for example, the nodes Np and Nn are grounded, and the jump of the potential of the signal PEO is suppressed.

At time t66, the signal RGS is changed from the “H” level to the “L” level, and the pulse of the signal RGS is lost. As a result, the switch elements 38s1 and 38s2 are changed from the on state to the off state. A period from the timet65 to the time t66 is a period d6.

The operation from timet67 to time t70 is similar to the operation from the timet14 to the time t17 of the embodiment.

Thus, the operation of the fourth modification ends.

The fourth modification also achieves effects equivalent to those of the embodiment.

Also in the fourth modification, similarly to the third modification, generation of unnecessary radiation caused by the negative potential pulses of the signals PEO and NEO can be suppressed. In addition, it is possible to suppress the occurrence of malfunction due to unnecessary radiation.

3 Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A digital isolator of an edge transmission type, comprising:
an edge detection circuit that detects an edge of a first signal according to an input signal having a first level or a second level and outputs a first detection signal generated using an edge of a first polarity of the first signal and a second detection signal generated using an edge of a second polarity of the first signal different from the first polarity;
a refresh circuit that generates a refresh pulse based on the input signal and outputs a first refresh signal generated corresponding to the first level using the refresh pulse and a second refresh signal generated corresponding to the second level using the refresh pulse;
a driving buffer circuit that outputs a first drive signal generated using the first detection signal and the first refresh signal and a second drive signal generated using the second detection signal and the second refresh signal;
an isolation element in which the first drive signal and the second drive signal are input to a primary side, a first edge signal corresponding to the first drive signal is output from a first output terminal on a secondary side, and a second edge signal corresponding to the second drive signal is output from a second output terminal on a secondary side;
a latch circuit that latches data generated using the first edge signal and the second edge signal and outputs an output signal corresponding to the data;
a first switch circuit including a first switch element that switches a conduction state between a reference potential and the first output terminal by using the output signal and a second switch element that switches a conduction state between the reference potential and the second output terminal;
a first control circuit that turns on one switch element of the first switch element and the second switch element and turns off the other switch element by using the output signal; and
a refresh detection circuit that outputs a negative potential detection signal according to whether the first edge signal or the second edge signal is lower than or equal to a first potential lower than the reference potential.

2. The digital isolator according to claim 1, wherein
the refresh detection circuit comprises:
a first power supply that applies power to a first node;
a third switch element having one end and a gate coupled to the first node, and another end grounded;
a first capacitor having one end coupled to the first output terminal;
a fourth switch element having one end coupled to another end of the first capacitor;
a fifth switch element having one end to which a first voltage is applied, another end coupled to another end of the fourth switch element, and a gate;
a sixth switch element having one end to which a second voltage is applied and a gate coupled to another end of the fourth switch element together with another end and the gate of the fifth switch element;
a seventh switch element having one end coupled to another end of the first capacitor and one end of the fourth switch element, a gate coupled to the first node, and another end grounded;
an eighth switch element having one end coupled to another end of the sixth switch element and another end grounded;
a second capacitor having one end coupled to the second output terminal;
a ninth switch element having one end coupled to another end of the second capacitor;
a tenth switch element having one end to which a third voltage is applied, another end coupled to another end of the ninth switch element, and a gate;
an eleventh switch element including one end to which a fourth voltage is applied and a gate coupled to the another end of the ninth switch element together with another end and the gate of the tenth switch element;
a twelfth switch element having one end coupled to the another end of the second capacitor and the one end of the ninth switch element, a gate coupled to the first node, and another end grounded; and
a thirteenth switch element having one end coupled to another end of the eleventh switch element and another end grounded, and
the refresh detection circuit outputs a negative potential detection signal using a potential at the another end of the sixth switch element and a potential at the another end of the eleventh switch element.

3. The digital isolator according to claim 2, wherein
a gate of the eighth switch element and a gate of the thirteenth switch element are coupled to the first node.

4. The digital isolator according to claim 2, wherein
the refresh detection circuit further comprises:
a third capacitor having one end coupled to the first output terminal in parallel with one end of the first capacitor and another end coupled to the gate of the eighth switch element;
a first resistor having one end coupled to the gate of the eighth switch element and the another end of the third capacitor, and another end coupled to the first node;
a fourth capacitor having one end coupled to the second output terminal in parallel with the one end of the second capacitor, and another end coupled to the gate of the thirteenth switch element; and
a second resistor having one end coupled to the gate of the thirteenth switch element and the another end of the fourth capacitor, and another end coupled to the first node.

5. The digital isolator according to claim 4, wherein
the refresh detection circuit further comprises:
a fifth capacitor having one end coupled to the another end of the first capacitor, and another end coupled to the one end of the fourth switch element and the one end of the seventh switch element;
a third resistor having one end coupled to the another end of the first capacitor and the one end of the fifth capacitor, and another end grounded;
a sixth capacitor having one end coupled to the another end of the second capacitor, and another end coupled to the one end of the ninth switch element and the one end of the twelfth switch element; and
a fourth resistor having one end coupled to the another end of the second capacitor and the one end of the sixth capacitor, and another end grounded.

6. The digital isolator according to claim 1, further comprising:
a first logical sum operation circuit that outputs a fourth signal generated by a logical sum operation of a second signal according to the first edge signal and a third signal according to the second edge signal; and
a second logical sum operation circuit that outputs a fifth signal generated by a logical sum operation of the negative potential detection signal and the fourth signal.

7. The digital isolator according to claim 1, wherein
the first control circuit comprises:
a first delay circuit that outputs a first control signal obtained by delaying the output signal; and
an inverter that outputs a second control signal that is an inverted signal of the first control signal,
the first control signal is a signal used to turn on or off the first switch element, and
the second control signal is used to turn on or off the second switch element.

8. The digital isolator according to claim 7, further comprising
a second control circuit, wherein
the second control circuit comprises:
a second delay circuit that outputs a second signal obtained by delaying the negative potential detection signal;
a first logical sum operation circuit that outputs a third control signal generated by a logical sum operation of the first control signal and the second signal; and
a second logical sum operation circuit that outputs a fourth control signal generated by a logical sum operation of the second control signal and the second signal,
the third control signal is used to turn on or off the first switch element, and
the fourth control signal is used to turn on or off the second switch element.

9. The digital isolator according to claim 1, further comprising:
a first resistor coupled between the first output terminal and the latch circuit;
a second resistor coupled between the second output terminal and the latch circuit; and
a second switch circuit, wherein
the second switch circuit comprises:
a fifth switch element having one end coupled between the first resistor and the latch circuit and another end grounded;
a sixth switch element having one end coupled between the second resistor and the latch circuit and another end grounded; and
a second delay circuit that outputs a second signal obtained by delaying the negative potential detection signal, and
the second signal is used to turn on or off the fifth switch element and the sixth switch element.

10. The digital isolator according to claim 6, further comprising
a watchdog that stops output of the output signal by the latch circuit based on an interval of pulses of the fifth signal.

11. The digital isolator according to claim 1, wherein
the first switch circuit further comprises:
a first resistor having one end coupled to the first output terminal and another end coupled to a reference potential together with the first switch element; and
a second resistor having one end coupled to the second output terminal and another end coupled to a reference potential together with the second switch element.

12. The digital isolator according to claim 2, wherein
the refresh detection circuit further comprises
a logical sum operation circuit that generates the negative potential detection signal by a logical sum operation of a second signal based on the potential of the another end of the sixth switch element and the potential of the one end of the eighth switch element and a third signal based on the potential of the another end of the eleventh switch element and the potential of the one end of the thirteenth switch element.

13. The digital isolator according to claim 1, further comprising
a first delay circuit that generates the first signal by delaying the input signal and outputs the generated first signal to the edge detection circuit.

14. The digital isolator according to claim 1, wherein
the first drive signal is based on a logical sum operation of the first detection signal and the first refresh signal, and
the second drive signal is based on a logical sum operation of the second detection signal and the second refresh signal.

15. The digital isolator according to claim 1, wherein
the isolation element comprises:
a first coil having one end to which the first drive signal is input and another end to which the second drive signal is input; and
a second coil having one end that outputs the first edge signal and another end that outputs the second edge signal.
